(19) United States
(12) Patent Application Publication
(10) Pub. No.: US 2014/0037943 A1
(43) Pub. Date: Feb. 6, 2014

(54) COATED ARTICLE AND METHOD FOR MAKING SAME

(71) Applicant: DA-HUA CAO, Shenzhen City (CN)

(72) Inventor: DA-HUA CAO, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/628,491

(22) Filed: Sep. 27, 2012

(30) Foreign Application Priority Data
Aug. 3, 2012 (CN) 2012102749222

(51) Int. Cl. C23C 14/35; C23C 14/16; B32B 15/04

(52) U.S. Cl. 428/336; 428/450; 204/192.16

(57) ABSTRACT

A coated article includes a metal substrate, a TiSiN layer formed on the metal substrate, and a TiN layer formed on the TiSiN layer. The TiSiN layer consists essentially of elemental Ti, elemental Si, and elemental N in non-homogenous deposition. The elemental Si within the TiSiN layer has a mass percentage gradually decreasing from the bottom of the TiSiN layer near the substrate to the top of the TiSiN layer away from the substrate. The elemental N has a mass percentage gradually increasing from the bottom of the TiSiN layer near the substrate to the top of the TiSiN layer away from the substrate. The TiN layer consists essentially of elemental Ti and elemental N. A method for making the coated article is also described.

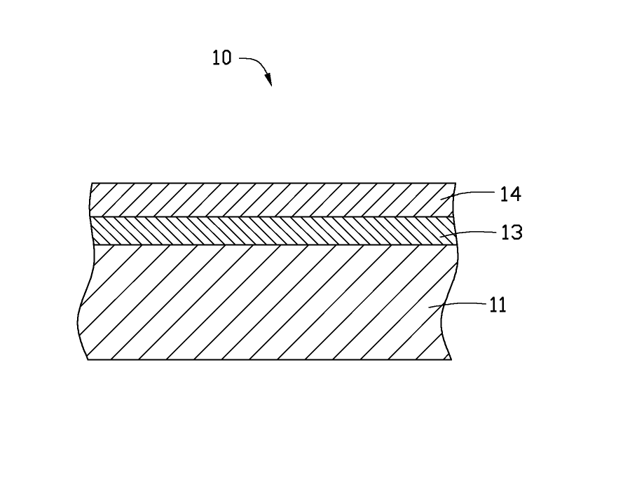

### BACKGROUND

1. Technical Field

The present disclosure generally relates to coated articles and a method for manufacturing the coated articles, particularly coated articles having high hardness coatings and a method for making the coated articles. 2. Description of Related Art

Due to its having high hardness and good abrasion resistance, titanium nitride (TiN) coatings are widely used on cutting tools, measuring tools, and dies as a functional coating. Furthermore, due to having a golden color, TiN coatings are also widely used on household appliances, electronic devices, and watches as a decorative coating. However, TiN coatings are not always resistant enough to abrasion to satisfy demand.

Therefore, there is room for improvement within the art.

### BRIEF DESCRIPTION OF THE DRAWING

Many aspects of the disclosure can be better understood with reference to the following FIGURE. The components in the FIGURE are not necessarily drawn to scale, the emphasis instead being placed upon clearly illustrating the principles of the disclosure.

The FIGURE is a cross-sectional view of an exemplary embodiment of the present coated article.

### DETAILED DESCRIPTION

The FIGURE shows an exemplary embodiment of a coated article 10. The coated article 10 includes a metal substrate 11, a titanium-silicon-nitride (TiSiN) layer 13 directly formed on the substrate 11, and a titanium-nitride (TiN) layer 14 directly formed on the TiSiN layer 13. As used in this disclosure, “directly” means a surface of one layer is in contact with a surface of another layer.

The substrate 11 may be made of iron-based alloy, such as stainless steel. The substrate 11 may also be made of titanium or aluminum alloys.

The TiSiN layer 13 consists essentially of elemental Ti, elemental Si, and elemental N. The TiSiN layer 13 is not homogenous. In the TiSiN layer 13, the mass percentage of elemental Si gradually decreases from the bottom of the TiSiN layer 13 near the substrate 11 to the top of the TiSiN layer 13 away from the substrate 11. The mass percentage of elemental Si gradually decreases from a largest value of about 10-%-13% to a smallest value of about 0. The mass percentage of elemental N gradually increases from the bottom of the TiSiN layer 13 near the substrate 11 to the top of the TiSiN layer 13 away from the substrate 11. The mass percentage of elemental N gradually increases from a smallest value of about 0-3% to a largest value of about 15%-20%. The mass percentage of elemental Ti is in a consistent range of about 67% to about 85%. The thickness of the TiSiN layer 13 may be about 0.8 μm to about 2.4 μm.

The TiN layer 14 is a homogeneous layer and consists essentially of elemental Ti and elemental N. In the TiN layer 14, the mass percentage of elemental Ti is in a consistent range of about 70% to about 80%. The mass percentage of elemental N is in a consistent range of about 20% to about 30%. The thickness of the TiN layer 14 may be about 1.5 μm to about 2.0 μm. The TiN layer 14 has a golden color.

The coated article 10 having the TiSiN layer 13 and the TiN layer 14 has a surface hardness of about 700 HV (25 gf) to about 800 HV (25 gf).

The TiSiN layer 13 contains elemental Si. The elemental Si may exist in the TiSiN layer 13 as silicon nitride (Si₃N₄) which has a high hardness and excellent oxidation resistance at high temperatures, thereby providing a high hardness and good oxidation resistance at high temperatures for the coated article 10. Moreover, the mass percentage of the elemental Si in the TiSiN layer 13 gradually decreases from the bottom of the TiSiN layer 13 near the substrate 11 to the top of the TiSiN layer 13 away from the substrate 11, which reduces any internal stress between the TiSiN layer 13 and the TiN layer 14 and further improves the bond between TiSiN layer 13 and the TiN layer 14. The TiN layer 14 provides a golden color for the coated article.

The TiSiN layer 13 and the TiN layer 14 may be formed by magnetron sputtering.

A method for manufacturing the coated article 10 may include the following steps: providing the metal substrate 11; magnetron sputtering the TiSiN layer 13 on the substrate 11; and magnetron sputtering the TiN layer 14 on the TiSiN layer 13.

Magnetron sputtering the TiSiN layer 13 includes sputtering conditions where silane and nitrogen are used as reaction gases; applying an electric power to titanium targets to sputter the titanium target material onto the substrate 11 and deposit the TiSiN layer 13. During the deposition process, the flow rate of the silane is gradually decreased from an initial range of about 30 to 40 standard cubic centimeters per minute (sccm) to a minimum value of about zero sccm; the flow rate of the nitrogen is gradually increased from an initial range of about zero to 10 sccm, until achieving a peak range of about 90 to 100 sccm.

Magnetron sputtering the TiN layer 14 includes sputtering conditions where nitrogen is used as reaction gas; applying an electric power to titanium targets to sputter the titanium target material onto the TiSiN layer 13 and deposit the TiSiN layer 13.

The sputtering conditions also include: using an inert gas (such as argon) having a flow rate of about 150 sccm to about 250 sccm as a sputtering gas; applying a bias voltage of about −50 V to about −200 V to the substrate 11; conducting the magnetron sputtering at an sputtering pressure of about 0.3 Pa to about 0.7 Pa and at a sputtering temperature of about 130° C. to about 180° C. The sputtering pressure denotes an absolute internal pressure of a chamber for implementing a sputtering operation during the magnetron sputtering process. The sputtering temperature denotes an internal temperature of the chamber for implementing a sputtering operation during the magnetron sputtering process.

The electric power may be provided by any power source for magnetron sputtering, such as an intermediate frequency power source.

Specific examples of making the coated article 10 and comparison examples are described. The specific examples mainly emphasize the different process parameters of making the coated article 10.

### EXAMPLE 1

A sample of 304-type stainless steel substrate 11 was cleaned with alcohol in an ultrasonic cleaner.

The substrate 11 was placed into a vacuum chamber of a magnetron sputtering machine (not shown). The magnetron sputtering machine further included at least one pair of titanium targets held inside the vacuum chamber. The substrate 11 was rotated relative to the titanium targets on a bracket in the chamber.

Deposition of the TiSiN layer 13: The vacuum chamber was evacuated to maintain an internal pressure of about 6.0×10⁻³ Pa. The internal temperature of the vacuum chamber was maintained at about 130° C. (namely the sputtering temperature). Argon, silane, and nitrogen were simultaneously fed into the vacuum chamber. The flow rate of the argon was about 200 sccm. The initial flow rate of the silane was about 30 sccm. The initial flow rate of the nitrogen was about 0 sccm. During the deposition process, the flow rate of the silane decreased at a rate of about 1 sccm per 3 minutes, until achieving a minimum value of about 0 sccm; the flow rate of the nitrogen increased at a rate of about 3 sccm per 2 minutes, until achieving a peak value of about 90 sccm. The argon, silane, and nitrogen created an internal pressure (namely the sputtering pressure) of about 0.3 Pa. A bias voltage of about −100 V was applied to the substrate 11. About 10 kW of power was applied to the titanium targets, thereby depositing a TiSiN layer 13 on the substrate 11. The deposition of the TiSiN layer 13 took about 90 minutes. The thickness of the TiSiN layer 13 was about 1.5 μm. In the TiSiN layer 13, the mass percentage of elemental Si gradually decreased from about 13% at the bottom of the TiSiN layer 13 near the substrate 11 to about 0 at the top of the TiSiN layer 13 away from the substrate 11; the mass percentage of elemental N gradually increased from about 0 at the bottom of the TiSiN layer 13 near the substrate 11 to about 20% at the top of the TiSiN layer 13 away from the substrate 11; the mass percentage of elemental Ti was consistently about 76%.

Deposition of the TiN layer 14: The power applied to the titanium targets was adjusted to 12 kW. Silane gas flow was switched off. The flow rate of the nitrogen was adjusted to about 100 sccm, depositing a TiN layer 14 on the TiSiN layer 13, with other parameters the same as during deposition of the TiSiN layer 13. The deposition of the TiN layer 14 took about 90 minutes. The thickness of the TiN layer 14 was about 1.5 μm. In the TiN layer 14, the mass percentage of elemental Ti was consistently about 70%; the mass percentage of elemental N was consistently about 30%.

The product of example 1 was tested to have a surface hardness of about 750 HV (25 gf).

### EXAMPLE 2

A sample of 304-type stainless steel substrate 11 was cleaned with alcohol in an ultrasonic cleaner.

The substrate 11 was placed into the vacuum chamber of the magnetron sputtering machine used in example 1. At least one pair of titanium targets held inside the vacuum chamber. The substrate 11 was rotated relative to the titanium targets on a bracket in the chamber.

Deposition of the TiSiN layer 13: The vacuum chamber was evacuated to an internal pressure of about 5.0×10⁻³ Pa. The internal temperature of the vacuum chamber was about 180° C. (namely the sputtering temperature). Argon, silane, and nitrogen were fed into the vacuum chamber. The flow rate of the argon was about 150 sccm. The initial flow rate of the silane was about 30 sccm. The initial flow rate of the nitrogen was about 10 sccm. During the deposition process, the flow rate of the silane was decreased at a rate of about 1 sccm per 2 minutes, until a minimum value of about 0 sccm was achieved; the flow rate of the nitrogen was increased at a rate of about 3 sccm per 2 minutes, until a peak value of about 100 sccm was achieved. The argon, silane, and nitrogen created an internal pressure (namely the sputtering pressure) of about 0.7 Pa. A bias voltage of about −150 V was applied to the substrate 11. About 16 kW of power was applied to the titanium targets, depositing a TiSiN layer 13 on the substrate 11. The deposition of the TiSiN layer 13 took about 60 minutes. The thickness of the TiSiN layer 13 was about 2.0 μm. In the TiSiN layer 13, the mass percentage of elemental Si gradually decreased from about 10% at the bottom of the TiSiN layer 13 near the substrate 11 to about 0 at the top of the TiSiN layer 13 away from the substrate 11; the mass percentage of elemental N gradually increased from about 3% at the bottom of the TiSiN layer 13 near the substrate 11 to about 18% at the top of the TiSiN layer 13 away from the substrate 11; the mass percentage of elemental Ti was consistently about 73%.

Deposition of the TiN layer 14: The power applied to the titanium targets was adjusted to 17 kW. Silane gas flow was switched off. The flow rate of the nitrogen was adjusted to about 120 sccm, depositing a TiN layer 14 on the TiSiN layer 13, with other parameters the same as during deposition of the TiSiN layer 13. The deposition of the TiN layer 14 took about 60 minutes. The thickness of the TiN layer 14 was about 2.0 μm. In the TiN layer 14, the mass percentage of elemental Ti was consistently about 80%; the mass percentage of elemental N was consistently about 20%.

The product of example 1 was tested to have a surface hardness of about 800 HV (25 gf).

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a metal substrate;
a TiSiN layer directly formed on the metal substrate, the TiSiN layer consisting essentially of elemental Ti, elemental Si, and elemental N, the elemental Si within the TiSiN layer having a mass percentage gradually decreasing from the bottom of the TiSiN layer near the substrate to the top of the TiSiN layer away from the substrate, the elemental N having a mass percentage gradually increasing from the bottom of the TiSiN layer near the substrate to the top of the TiSiN layer away from the substrate; and
a TiN layer directly formed on the TiSiN layer, the TiN layer consisting essentially of elemental Ti and elemental N.

2. The coated article as claimed in claim 1, wherein in the TiSiN layer, the mass percentage of elemental Si gradually decreases from a largest value of about 10%-13% to a smallest value of about 0; the mass percentage of elemental N gradually increases from a smallest value of about 0-3% to a largest value of about 15%-20%; the mass percentage of elemental Ti is in a consistent range of about 67% to about 85%.

3. The coated article as claimed in claim 1, wherein the thickness of the TiSiN layer is about 0.8 μm to about 2.4 μm.

4. The coated article as claimed in claim 1, wherein in the TiN layer, the mass percentage of elemental Ti is in a consistent range of about 70% to about 80%; the mass percentage of elemental N is in a consistent range of about 20% to about 30%.

5. The coated article as claimed in claim 1, wherein the thickness of the TiN layer is about 1.5 μm to about 2.0 μm.

6. A method for manufacturing a coated article, comprising:
providing a metal substrate;
magnetron sputtering a TiSiN layer directly on the metal substrate, the TiSiN layer consisting essentially of elemental Ti, elemental Si, and elemental N, the elemental Si within the TiSiN layer having a mass percentage gradually decreasing from the bottom of the TiSiN layer near the substrate to the top of the TiSiN layer away from the substrate, the elemental N having a mass percentage gradually increasing from the bottom of the TiSiN layer near the substrate to the top of the TiSiN layer away from the substrate; and
magnetron sputtering a TiN layer directly on the TiSiN layer, the TiN layer consisting essentially of elemental Ti and elemental N.

7. The method of claim 6, wherein magnetron sputtering the TiSiN layer includes using silane and nitrogen as reaction gases; applying an electric power to titanium targets to sputter the titanium target material onto the metal substrate; during the deposition process, the flow rate of the silane is gradually decreased from an initial range to a minimum value of about zero sccm; the flow rate of the nitrogen is gradually increased from an initial range of about zero to 10 sccm, until achieving a peak range.

8. The method of claim 7, wherein the initial range of flow rate of the silane is about 30 to 40 sccm.

9. The method of claim 7, wherein the peak range of flow rate of the nitrogen is about 90 to 100 sccm.

10. The method of claim 7, wherein magnetron sputtering the TiSiN layer further includes using an inert gas having a flow rate of about 150 sccm to about 250 sccm as a sputtering gas; applying a bias voltage of about −50 V to about −200 V to the metal substrate; conducting the magnetron sputtering at an sputtering pressure of about 0.3 Pa to about 0.6 Pa and at a sputtering temperature of about 130° C. to about 180° C.

11. The method of claim 6, wherein magnetron sputtering the TiN layer includes using nitrogen as reaction gas; applying an electric power to titanium targets to sputter the titanium target material onto the TiSiN layer.

12. The method of claim 11, wherein magnetron sputtering the TiN layer further includes using an inert gas having a flow rate of about 150 sccm to about 250 sccm as a sputtering gas; applying a bias voltage of about −50 V to about −200 V to the metal substrate; conducting the magnetron sputtering at an sputtering pressure of about 0.3 Pa to about 0.6 Pa and at a sputtering temperature of about 130° C. to about 180° C.
